(19) United States
(12) Patent Application Publication
(10) Pub. No.: US 2012/0000766 A1
(43) Pub. Date: Jan. 5, 2012

(54) METHOD FOR MANUFACTURING SCANDIUM ALUMINUM NITRIDE FILM

(75) Inventors: Akihiko Teshigahara, Nisshin-city (JP); Kazuhiko Kano, Toyoake-city (JP); Morito Akiyama, Tosu-city (JP); Tatsuo Tabaru, Tosu-city (JP); Keiko Nishikubo, Tosu-city (JP)

(73) Assignee: DENSO CORPORATION, Kariya-city (JP)

(21) Appl. No.: 13/171,806

(22) Filed: Jun. 29, 2011

(30) Foreign Application Priority Data
Jul. 1, 2010 (JP) 2010-151289

(51) Int. Cl. C23C 14/34

(52) U.S. Cl. 204/192.15

(57) ABSTRACT

A method for manufacturing a scandium aluminum nitride film includes: sputtering a scandium aluminum alloy target under atmosphere including nitrogen gas so that a thin film is deposited on a substrate. Since the scandium aluminum nitride film is manufactured with using one alloy target, a composition of the film is maintained even when the sputtering time is long. Further, the above method is capable of being performed by a mass production sputtering apparatus.

### CROSS REFERENCE TO RELATED APPLICATION

This application is based on Japanese Patent Application No. 2010-151289 filed on Jul. 1, 2010, the disclosure of which is incorporated herein by reference.

### TECHNICAL FIELD

The present invention relates to a method for manufacturing a scandium aluminum nitride film.

### BACKGROUND

A scandium aluminum nitride film is suitably used for a light emission layer of a light emitting diode (i.e., LED) for emitting light having a wavelength in a wide range and for a Piezoelectric thin film in a MEMS (i.e., micro-electro-mechanical system).

The scandium aluminum nitride film made of ScₓAl₁₋ₓN_{y} is manufactured by a dual target sputtering method with using an aluminum target and a scandium target, which are sputtered at the same time. The manufacturing method is disclosed in JP-A-2009-10926.

However, in the above method, it is difficult to maintain a composition in the film for a long time.

Further, when a sputtering apparatus is large for high volume production, since two targets are used, it is difficult to uniform a composition on a whole surface of the film.

Specifically, in the dual target sputtering method, it is necessary to control the sputtering apparatus that a sputtering condition of each target of two types of targets is maintained so that a composition of the film is-not changed. However, in the dual target sputtering method, the targets may be worn out when the targets are used for a long time. Thus, the shape of the target is changed. Further, a wearing speed of each target depends on a type of metal. Accordingly, the sputtering speed of the target is changed. Thus, it is very difficult to maintain the composition of the film for a long time.

Further, in case of a large scale sputtering apparatus, an area, in which the composition is uniformed, is very limited. Thus, a productivity of the apparatus is small, compared with a same scale apparatus.

### SUMMARY

In view of the above-described problem, it is an object of the present disclosure to provide a method for manufacturing a scandium aluminum nitride film. The method provides to maintain a composition of the scandium aluminum nitride film for a long time, and the method is performed with using a large scale apparatus.

According to an example aspect of the present disclosure, a method for manufacturing a scandium aluminum nitride film includes: sputtering a scandium aluminum alloy target under atmosphere including nitrogen gas so that a thin film is deposited on a substrate. In this method, since the scandium aluminum nitride film is manufactured with using one alloy target, a composition of the film is substantially constant even when a sputtering time is long. Further, the above method is capable of being performed by a mass production sputtering apparatus. Therefore, it is not necessary to reform a conventional apparatus and to introduce a new apparatus. An initial cost for manufacturing the scandium aluminum nitride film is reduced.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing a X ray diffraction pattern of a thin film according to a first embodiment;

FIG. 2 is a graph showing a relationship between a scandium concentration in the thin film and a sputtering time;

FIG. 3 is a graph showing a relationship between a nitrogen concentration and a Piezoelectric responsibility in a thin film according to second and tenth to twelfth embodiments;

FIG. 4 is a diagram showing a Piezoelectric response of various thin films according to second to ninth embodiments; and

FIG. 5 is a diagram showing an unbiased variance in various factors.

### DETAILED DESCRIPTION

A method for manufacturing a scandium aluminum nitride film (i.e., a ScₓAl₁₋ₓN_{y} film) according to an example embodiment includes a step of sputtering with using a sputtering target made of an alloy of scandium aluminum (ScₓAl₁₋ₓ) in an atmosphere including a nitrogen gas.

In the above method, since a ScₓAl₁₋ₓ alloy target is used, a composition of the scandium aluminum nitride film is maintained for a long time, compared with a conventional dual target sputtering method. Thus, a large scale sputtering apparatus can be used.

A substrate, on which the scandium aluminum nitride film is formed, may be any substrate. For example, the substrate is made of silicon, sapphire, silicon nitride, gallium nitride, lithium niobate, niobium tantalite, crystal, glass, metal, stainless, inconel alloy, a polymer film such as a polyimide film and the like.

The scandium aluminum alloy is formed by a vacuum melting method from metallic aluminum and metallic scandium as raw material.

A ratio between Sc and Al in the scandium aluminum alloy is determined by a target composition of a thin film. For example, when a total amount of Sc atoms and Al atoms is defined as 100 at %, a content percentage of the scandium atoms in the film can be controlled in a range between 0 at % and 50 at %. In view of high Piezoelectric response of the film, it is preferable to set the content percentage of the scandium atoms in a range between 10 at % and 45 at %.

An electric power density of the ScₓAl₁₋ₓ alloy target may be any. For example, the electric power density of the ScₓAl₁₋ₓ alloy target is in a range between 4.3 W/cm² and 14 W/cm². It is preferable to set the electric power density of the ScₓAl₁₋ₓ alloy target in a range between 6.5 W/cm² and 11 W/cm². Here, the electric power density of the ScₓAl₁₋ₓ alloy target is calculated by dividing the sputtering electric power with an area of the target.

The atmosphere in a sputtering process is not limited as long as the atmosphere includes nitrogen gas. For example, the atmosphere is nitrogen atmosphere, mixed gas atmosphere and the like. The mixed gas atmosphere includes nitrogen gas and inert gas such as argon gas.

When the sputtering process is performed in the mixed gas atmosphere, the content percentage of the nitrogen gas is, for example, in a range between 25 vol % and 50 vol %. In view of high Piezoelectric response of the film, it is preferable to set the content percentage of the nitrogen gas in a range between 25 vol % and 35 vol %.

The sputtering process is performed under pressure in a range between 0.3 Pa and 0.8 Pa. Preferably, the sputtering process is performed under pressure in a range between 0.3 Pa and 0.4 Pa.

A substrate temperature in the sputtering process is not limited. For example, the substrate temperature may be in a range between 18° C. and 600° C. Preferably, the substrate temperature is in a range between 200° C. and 400° C.

The content percentage of the scandium atoms in the ScₓAl₁₋ₓ alloy target and in the ScₓAl₁₋ₓN_{y} film is analyzed by an energy dispersive X-ray fluorescence analyzer (e.g., EX-320X made by Horiba Ltd.).

The Piezoelectric response of an aluminum nitride film including scandium atoms, i.e., the ScₓAl₁₋ₓN_{y} film is measured by a Piezo meter (e.g., PM100 made by Piezotest Pte. Ltd.) under a condition that weight is 0.25N, and a frequency is 110 Hz.

A X-ray diffraction intensity is measured by a full automatic X-ray diffraction apparatus (M03X-HF made by Mac Science) with using a CuKα line as a X-ray source.

(Manufacturing Method of Sc_{0.42}Al_{0.58} Alloy Target)

Metallic aluminum and metallic scandium are used as raw material, and the Sc_{0.42}Al_{0.58} alloy target is manufactured by a vacuum melting method.

Specifically, the metallic aluminum and the metallic scandium are melted in vacuum such that a concentration ratio of elements between scandium and aluminum is set to 0.42:0.58. After the composition of melted metal is homogeneous, the melted metal is cooled and solidified. Then, the solidified metal is processed to be a target. Thus, the Sc_{0.42}Al_{0.58} alloy target is formed.

### FIRST EMBODIMENT

The Sc_{0.42}Al_{0.58} alloy target is sputtered in nitrogen atmosphere with using a silicon substrate. Thus, the scandium aluminum nitride film is formed on the silicon substrate.

The sputtering apparatus is a radio frequency magnetron sputtering apparatus (made by Anelva Corporation). The sputtering condition is that the sputtering pressure is 0.3 Pa, the nitrogen concentration in the atmosphere is 40 vol %, the electric power density of the target is 11 W/cm², the substrate temperature is 300° C., and the sputtering time is 200 minutes.

Further, the pressure in a sputtering chamber is reduced to be equal to or lower than 5×10⁻⁵ Pa. Mixed gas of argon gas and nitrogen gas is introduced into the chamber. The purity of the argon gas is 99.999 vol %, and the purity of the nitrogen gas is 99.999 vol %. The target is preliminary sputtered for three minutes under the same condition as a deposition process before the scandium aluminum nitride film is formed on the silicon substrate.

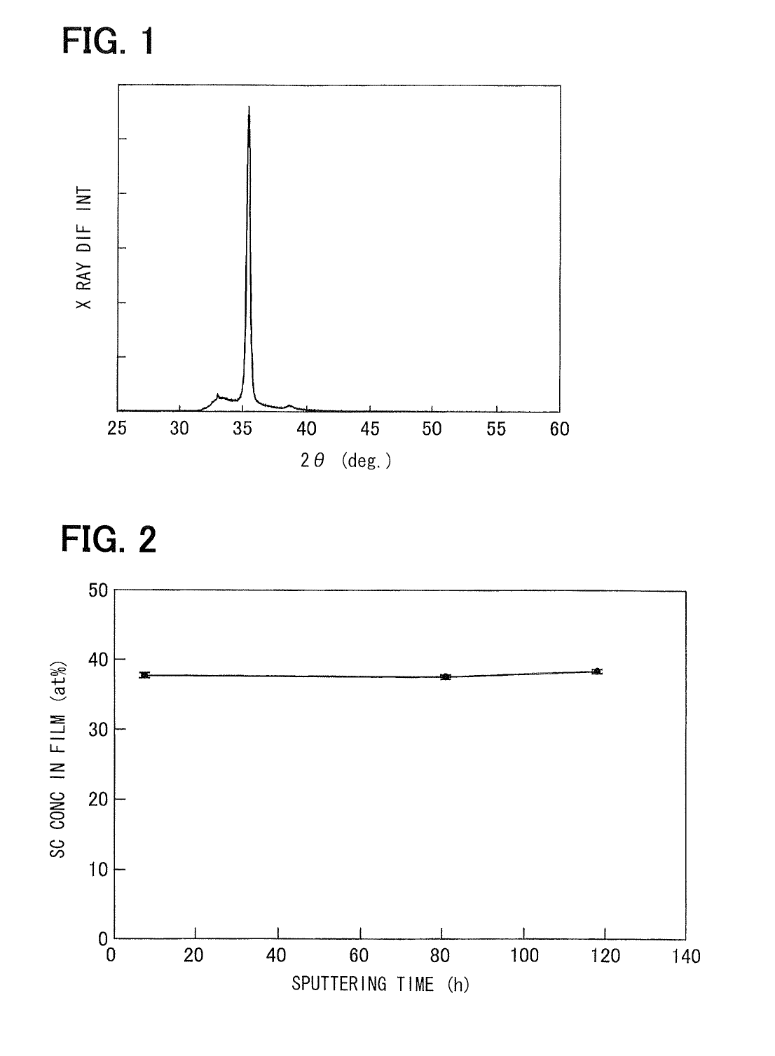

The X-ray diffraction pattern of the obtained scandium aluminum nitride film is shown in FIG. 1. As shown in FIG. 1, a diffraction peak is observed at 35 degrees. Therefore, the ScₓAl₁₋ₓN_{y} film is formed.

When the composition of the ScₓAl₁₋ₓN_{y} film is measured, and a total amount of Sc atoms and Al atoms is defined as 100 at %, the content percentage of the scandium atoms is 37 at %. Thus, the content percentage of the scandium atoms in the Sc_{0.42}Al_{0.58} alloy target is 42 at %, and therefore, the content percentage of the scandium atoms in the Sc_{0.42}Al_{0.58} alloy target is reduced to 37 at %. Further, the Piezoelectric response of the ScₓAl₁₋ₓN_{y} film is 18 pC/N.

Further, a relationship between the sputtering time and the content percentage of the scandium atoms in the ScₓAl₁₋ₓN_{y} film is shown in FIG. 2. As shown in FIG. 2, since the Sc_{0.42}Al_{0.58} alloy target is used, even when the sputtering time is long, the composition of the ScₓAl₁₋ₓN_{y} film is substantially constant.

The ScₓAl₁₋ₓN_{y} film is formed by a conventional dual target sputtering method. Specifically, the sputtering apparatus is a radio frequency magnetron sputtering apparatus (made by Anelva Corporation). The sputtering condition is that the sputtering pressure is 0.25 Pa, the nitrogen concentration in the atmosphere is 40 vol %, the electric power density of the Sc target is 8.8 W/cm², the electric power density of the Al target is 8.6 W/cm², the substrate temperature is 400° C., and the sputtering time is 180 minutes. The Piezoelectric response of the ScₓAl₁₋ₓN_{y} film by the conventional dual target sputtering method is 18 pC/N, which is the same as the ScₓAl₁₋ₓN_{y} film by the above method according to the first embodiment.

In the first embodiment, since the Sc_{0.42}Al_{0.58} alloy target is used, the composition of the ScₓAl₁₋ₓN_{y} film is not changed substantially even when the Sc_{0.42}Al_{0.58} alloy target is used for a long time, compared with the conventional dual target sputtering method. Further, the Piezoelectric response of the ScₓAl₁₋ₓN_{y} film according to the first embodiment is stably provided.

### SECOND TO NINTH EMBODIMENTS

In order to increase the Piezoelectric response, the sputtering condition is changed with using L9 orthogonal coordinates according to an experimental design method (analysis of variation).

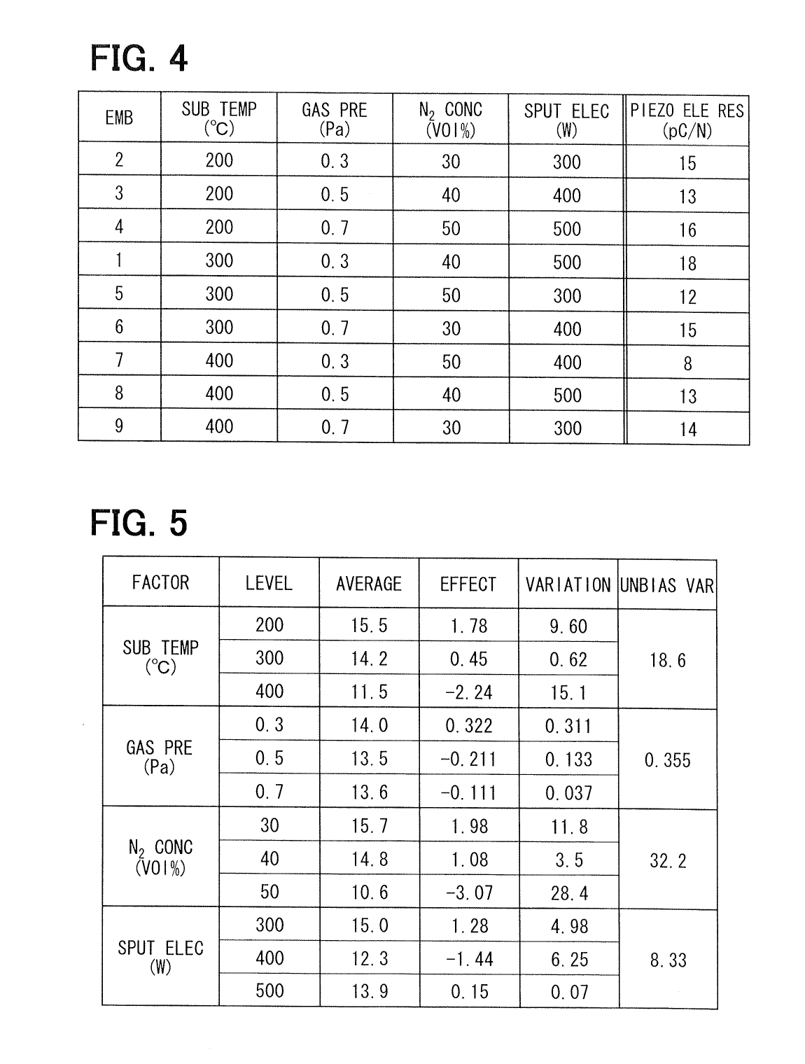

Specifically, the substrate temperature, the gas pressure, the nitrogen gas concentration in the gas and the sputtering electric power are changed according to the manufacturing factors in FIG. 4. Other parameters are the same as the first embodiment. Thus, various thin films are manufactured. FIG. 5 shows a result of the analysis of variation with regard to nine sputtering conditions in FIG. 4.

As a result, the unbiased variance of the nitrogen concentration is the highest, so that the nitrogen concentration is important control factor.

### TENTH TO TWELFTH EMBODIMENTS

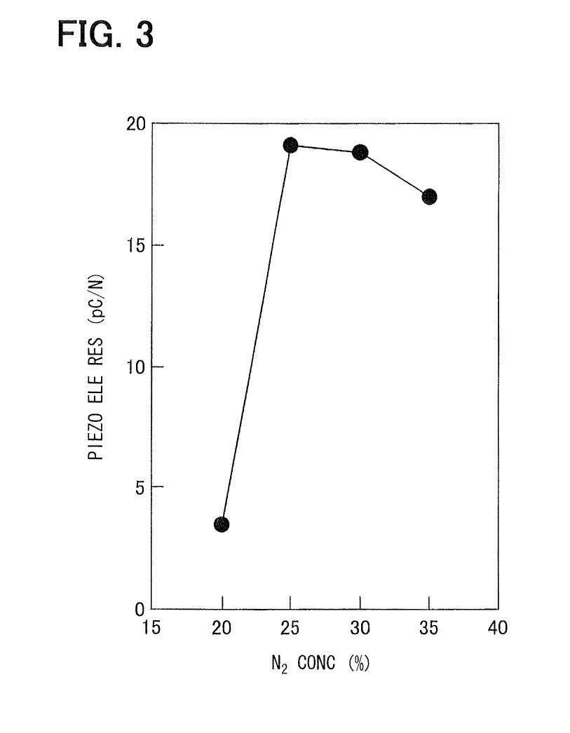

According to the result of the analysis of variation, the nitrogen gas concentration is changed to 20 vol %, 25 vol % and 35 vol %. Other parameters are the same as the second embodiment. Thus, various thin films are manufactured. The result of the thin films is shown in FIG. 3.

FIG. 3 shows a relationship between the Piezoelectric response and the nitrogen gas concentration. As shown in FIG. 3, the Piezoelectric response of the ScₓAl₁₋ₓN_{y} film manufactured under the nitrogen gas concentration of 25 vol % is maximum. It is preferable to set the nitrogen gas concentration in a range between 25 vol % and 35 vol %.

The method for manufacturing the scandium aluminum nitride film according to the above embodiments provides to maintain the composition of the thin film during the long sputtering time. Thus, it is preferable to manufacture a light emission layer of a light emitting diode (i.e., LED) and a Piezoelectric thin film in a MEMS (i.e., micro-electro-mechanical system).

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A method for manufacturing a scandium aluminum nitride film comprising:
sputtering a scandium aluminum alloy target under atmosphere including nitrogen gas so that a thin film is deposited on a substrate.

2. The method according to claim 1,
wherein a nitrogen gas concentration in the atmosphere is in a range between 25 vol % and 35 vol %.

3. The method according to claim 1,
wherein a substrate temperature is in a range between 200° C. and 400° C.

4. The method according to claim 2,
wherein a content percentage of scandium atoms in the scandium aluminum alloy target is higher than 10 at %, and lower than 45 at %,
wherein a target electric power density is in a range between 6.5 W/cm² and 11 W/cm²,
wherein a sputtering pressure is in a range between 0.3 Pa and 0.4 Pa, and
wherein a substrate temperature is in a range between 200° C. and 400° C.
